(19) United States
(12) Patent Application Publication
(10) Pub. No.: US 2019/0019751 A1
(43) Pub. Date: Jan. 17, 2019

(54) FUSE FABRICATION METHOD

(71) Applicant: SHANGHAI HUALI MICROELECTRONICS CORPORATION, Shanghai (CN)

(72) Inventors: Fulong Qiao, Shanghai (CN); Qiang Zhang, Shanghai (CN); Yi Wang, Shanghai (CN); Pengkai Xu, Shanghai (CN)

(21) Appl. No.: 15/978,153

(22) Filed: May 13, 2018

Related U.S. Application Data
(62) Division of application No. 15/788,812, filed on Oct. 20, 2017.

(30) Foreign Application Priority Data
Jul. 11, 2017 (CN) 201710561178.7

(51) Int. Cl. H01L 23/525; H01L 21/3065; H01L 21/3205; H01L 21/3213; H01L 23/532

(52) U.S. Cl. CPC H01L 23/5256; H01L 21/3065; H01L 21/32055; H01L 21/32139; H01L 21/32135; H01L 21/32053; H01L 23/53209; H01L 23/53271

(57) ABSTRACT

The present invention discloses a polysilicon fuse fabrication method. The polysilicon fuse comprises a polysilicon fuse-link and two leading terminals, the polysilicon fuse-link comprises a substrate, a first insulating layer and a polysilicon melt. The substrate is formed with a groove, which is covered by the first insulating layer. The polysilicon melt is formed on the first insulating layer and is embedded in the groove. Since the polysilicon melt is embedded in the groove of the substrate, the polysilicon melt is separated away from the nearby devices on the substrate by a sufficient safety distance, which effectively reduce or eliminate the effects of the particles generated during the blowing of the polysilicon melt on the nearby devices.

### CROSS-REFERENCE TO RELAYED APPLICATION

This application is a divisional application of U.S. application Ser. No. 15/788,812 filed Oct. 20, 2017, which application claims the benefit of priority from Chinese patent application number 201710561178.7, filed on Jul. 11, 2017, the entire contents of which are incorporated herein by reference.

### FIELD OF THE INVENTION

The present invention relates to the field of semiconductor manufacturing technology, more particularly to a fabrication method of an embedded polysilicon fuse.

### BACKGROUND OF THE INVENTION

A fuse is an electrical safety device which blows by heat generated therein and disconnects a circuit when current in the circuit exceeds a specified value. The fuse is widely used in all kinds of programmable logic devices (abbr.: PLD). In general, the fuse can be classified into Aluminum fuse and polysilicon fuse. The polysilicon fuse is very suitable to be used in low current circuits since it has a characteristic of easy to be melt.

At present, the conventional polysilicon fuse is generally planar designed. Please refer to FIG. 1, FIG. 1 shows a schematic diagram of a structure of a polysilicon fuse in the prior art. As shown in FIG. 1, reference number 1 indicates a blown position of the polysilicon fuse, reference numbers 2 and 3 indicate leading terminals of the polysilicon fuse, and two horizontal lines at the reference number 1 indicate the fuse-link, which can also be called polysilicon fuse wire or fuse piece.

The small rectangle frame arranged in array at the leading terminals 2 and 3 indicate through holes (contacts). In order to prevent the through holes from being burned-out when the fuse-link is blown, the number of the through holes generally can be set plural. The fuse can be connected into a circuit by the through holes at the leading terminals 2 and 3. In order to electrically connect to the fuse-link at reference number 1 and keep consistent current through the circuit, the material of the large rectangle plate of the leading terminals 2 and 3 is the same as that of fuse-link, and both of them can be polysilicon. Herein, the fuse-link 1 and the leading terminals 2, 3 are located in a same plane.

The working principle of the above-mentioned fuse is as follows: when the current, which flows from the leading terminal 3 into the fuse-link 1, exceeds the specified value, the fuse-link will be blown, thereby interrupting the circuit between the leading terminals 2, 3 and providing overcurrent protection to the device connected by the leading terminal 2. However, there exists such a problem in the above fuse that the particles generated at the moment when the fuse is blown may affect the operation of nearby devices in a vertical direction.

In addition, the principle of the fuse is to utilize the characteristic of high resistance value and low melting point of the fuse-link (such as fuse wire or fuse piece). When the current in the fuse-link reaches a certain value, the higher the resistance of the fuse-link, the more the heat is generated by itself, resulting in a quick rise of temperature to the melting point to blow the fuse link, that is, a short blowing time. Therefore, the blowing time can be controlled by adjusting the resistance value of the fuse-link. According to the resistance equation R=μL/S (wherein ρ is the resistivity which is generally decided by the material of the conductor, L is the length of the conductor, S is cross-sectional area of the conductor), when the material and the length of the fuse-link is fixed, the resistance value increases as the cross-sectional area S decreases.

Please refer to FIG. 2, FIG. 2 shows a schematic diagram of a structure of a polysilicon fuse. As shown in FIG. 2, assuming that the current flows in the polysilicon fuse in a direction “b”, that is, the direction of the length L of the polysilicon fuse, then the cross-sectional area S is determined by the width “a” and the height “c” of the polysilicon fuse. Since the polysilicon fuse necessarily has a certain height, the width “a” of the polysilicon fuse is generally regarded as the critical dimension which can be adjusted in the process to change the resistance value of the polysilicon fuse and control the blowing time of the polysilicon fuse.

However, in order to manufacture a polysilicon fuse with a small width like 60 nm or below, it is necessary to use a high-end lithographic apparatus. Since such lithographic apparatus is very expensive, the production cost will be increased significantly.

### SUMMARY OF THE INVENTION

The object of the present invention is to overcome the above problems in the prior art and provide a polysilicon fuse and fabrication process thereof, which can effectively avoid or reduce the influence of the blown particles on the nearby devices on the substrate, and can adjust the critical dimension of the polysilicon melt as required at low cost.

In order to achieve the above object, the technical solutions of the present invention are as follows:

A polysilicon fuse comprising a polysilicon fuse-link and two leading terminals. wherein The polysilicon fuse-link comprises a substrate, a first insulating layer and a polysilicon melt. The substrate is formed with a groove, which is covered by the first insulating layer. The polysilicon melt is formed on the first insulating layer and is embedded within the groove.

Furthermore, the groove includes a groove opening, a groove sidewall and a groove bottom opposite to the groove opening; a width of the groove opening is larger than that of the groove bottom.

Furthermore, the groove includes a groove opening, a groove wall and a groove bottom opposite to the groove opening; the polysilicon melt located on the first insulating layer at the groove bottom has an insulating sidewall spacer.

Furthermore, the groove includes a groove opening, a groove wall and a groove bottom opposite to the groove opening; the polysilicon melt is located on the first insulating layer at the groove bottom and is spaced from the groove sidewall at two sides by a certain distance.

Furthermore, a width of the polysilicon melt is smaller than a length of the polysilicon melt; wherein, a length direction of the polysilicon melt is the same as a direction of current flow, a height direction of the polysilicon melt is from the first insulating layer at the groove bottom to the top of the polysilicon meltbottom, a width direction of the polysilicon melt is perpendicular to the length direction and the height direction.

Further, the width of the polysilicon melt is 55 nm-300 nm.

Further, a metal silicide layer is formed on the top of the polysilicon melt.

In order to achieve the above object, the present invention also includes the following technical solution:

A fabrication method of a polysilicon fuse, comprising the following steps:

S1: etching a substrate to form a groove in the substrate, and forming a first insulting layer on a surface of the substrate covering the groove;

: forming a polysilicon melt layer on the first insulting layer;

SS3: forming a second insulting layer on the polysilicon melt layer;

SS4: performing lithographic and etching processes to the second insulting layer and the polysilicon melt layer to form a polysilicon melt in the groove. Preferably, an isotropic etching is performed to the second insulting layer and the polysilicon melt layer.

Furthermore, the fabrication method also comprises step S5: removing the second insulting layer on the polysilicon melt by a wet etching process.

Further, the fabrication method also comprises step S6: forming an insulting sidewall spacer on two sides of the polysilicon melt.

Further, the fabrication method also comprises step S7: performing a self-aligned silicidation process to form a metal silicide layer on the top of the polysilicon melt.

From the above technical solutions, the present invention provides an embedded polysilicon fuse and a fabrication method thereof. Since the polysilicon melt is embedded in the groove of the substrate and is kept away from the nearby devices by a sufficient safety distance, the particles generated during the blowing of the polysilicon melt are blocked by the groove and will not be introduced into the nearby devices, such that the influence of the particles on the nearby devices can be reduced or eliminated. Furthermore, the critical dimension of the polysilicon melt can be effectively adjusted as required by using a general lithographic apparatus with an etching precision of 55 nm-300 nm, thereby efficiently saving the production cost.

### BRIEF DESCRIPTION OF THE DRAWINGS

FIG. 1 is a schematic diagram of a structure of a polysilicon fuse in the prior art.

FIG. 2 is a schematic diagram of a conductor.

FIG. 3 is a schematic diagram of a structure of a fuse-link of the fuse according to a preferred embodiment of the present invention.

FIG. 4 is a stereogram of a structure of two fuse-links according to the present invention.

FIG. 5 is a schematic diagram showing fabrication procedures of the fuse-link according to the present invention.

FIG. 6 is a diagram showing a relation between the width of the polysilicon melt and the dry etching time according to the present invention.

FIG. 7 is a schematic diagram showing the fuse-link and the nearby devices according to the present invention.

### DETAILED DESCRIPTION OF THE EMBODIMENTS

The specific embodiments of the present invention are described in detail below in combination with drawings.

It should be noted that, in the following specific embodiments, in order to clearly illustrate the structure of the present invention to facilitate the explanation, the structures in the drawings are not made in accordance with the general ratio, and local enlargement, deformation and simplification processing are made. Therefore, it should be avoided to understand this as a limitation on the present invention.

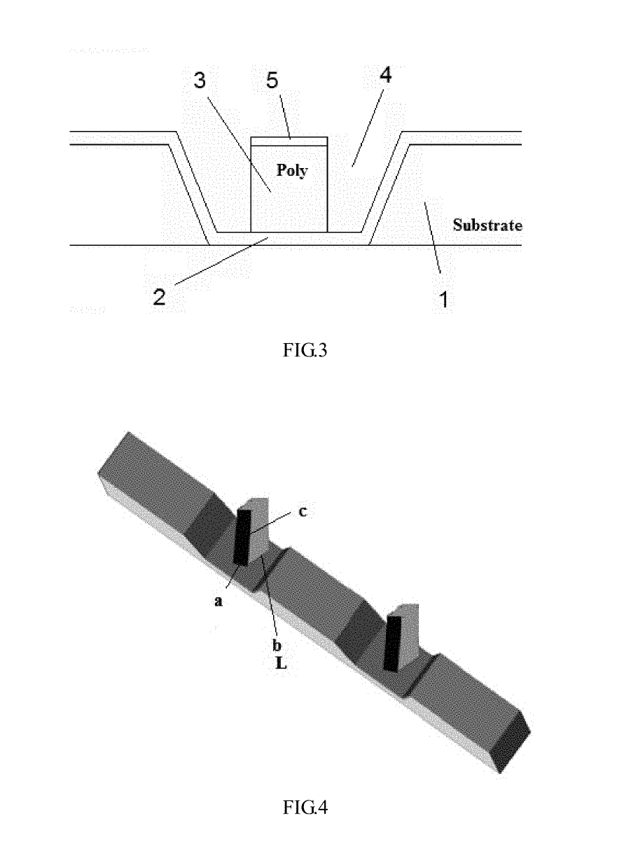

Please refer to FIG. 3, FIG. 3 is a cross-section diagram of a fuse-link in the polysilicon fuse according to a preferred embodiment of the present invention. In the embodiment of the present invention, it is the same as the prior art that the polysilicon fuse includes a polysilicon fuse-link and two leading terminals. The polysilicon fuse-link and the two leading terminals are all located on a substrate with an insulating layer.

In general, the polysilicon fuse-link is a polysilicon fuse wire or a fuse piece, which is connected between the two leading terminals. The two leading terminals are generally two large rectangle plates each provided with small rectangle through holes (contact) arranged in an array. In order to prevent the through holes from being burned-out when the polysilicon fuse-link is blown, the number of the small rectangle through holes generally can be set plural. The polysilicon fuse can be connected into a circuit by the through holes of the two leading terminals. In order to keep the electrical connection of the polysilicon fuse-link and consistent current flow, the material of the large rectangle plate of the two leading terminals is the same as that of fuse-link, and both of them can be polysilicon.

In the embodiment of the present invention, it is different from the prior art that, the fuse-link and the two leading terminals are not located in the same plane. Specifically, the fuse-link includes a substrate 1, a first insulating layer 2 and a polysilicon melt 3. A groove 4 is formed in the substrate 1, the first insulating layer 2 is formed on a surface of the substrate and covers the groove 4, the polysilicon melt 3 is formed on the first insulating layer 2 and is located in the groove 4 in an embedded state.

In the present embodiment, the substrate 1 can be a silicon substrate, the first insulating layer 2 can be a silicon dioxide insulating layer or a silicon nitride insulating layer, the polysilicon melt 3 can be formed by etching a polysilicon. The groove 4 includes a groove opening, a groove sidewall and a groove bottom opposite to the groove opening. Preferably, during the manufacturing process, the groove opening of the groove 4 is made wider than the shape of the groove bottom. That is, the width of the groove opening is larger than that of the groove bottom.

As shown in FIG. 3, the polysilicon melt 3 is located on the first insulating layer 2 at the groove bottom of the groove 4 and is spaced from the groove sidewall at two sides by a certain distance.

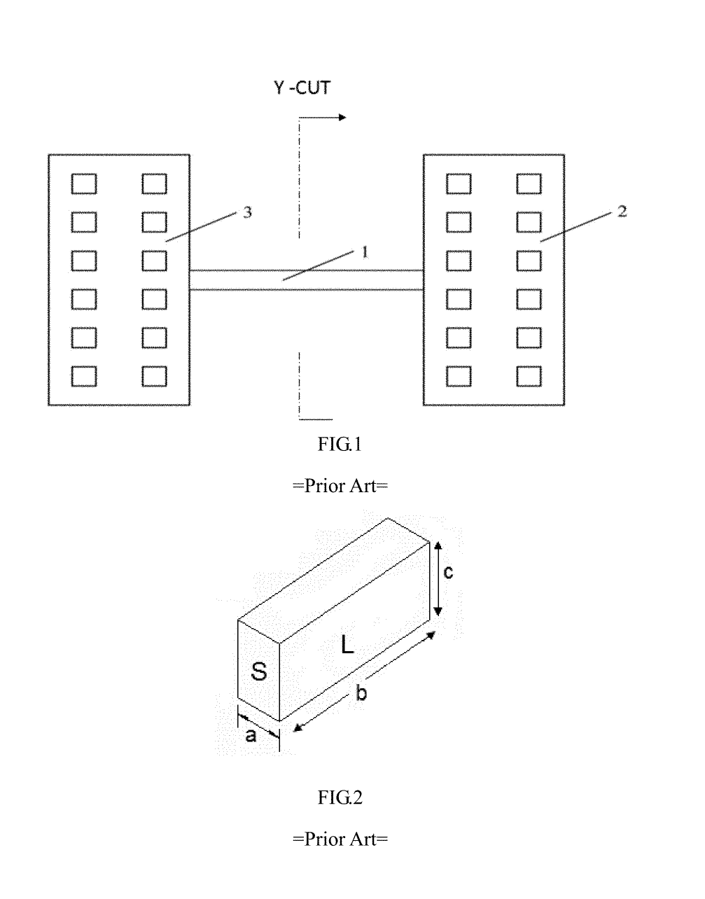

Please refer to FIG. 4, FIG. 4 is a stereogram showing two fuse-links of the fuse according to an embodiment of the present invention. In the embodiment of the present invention, the polysilicon melt 3 can be etched into a cuboid structure. In FIG. 4, the current flows in the polysilicon melt 3 in a length direction of the polysilicon melt 3. If the polysilicon melt 3 is regarded as a conductor, then the length “b” of the polysilicon melt 3 is the length L of the conductor shown in FIG. 2, and the cross-sectional area S is determined by the width “a” and the height “c” of the polysilicon melt 3. Since the polysilicon melt 3 necessarily has a certain height, the width a of the polysilicon melt is generally regarded as the critical dimension to be adjusted in the process, so as to change the resistance value of the polysilicon melt and control the blowing time of the polysilicon melt.

Therefore, in the embodiment of the present invention, in order to control the blowing time of the polysilicon melt, the polysilicon melt 3 can be extended in the width direction to approach or contact the groove sidewall at two sides, or can be extended in the width direction to approach or contact the groove wall at only one side, as long as to achieve the desired purpose of reducing the particles of the polysilicon melt ejected during the blowing. The height “c” of the polysilicon melt 3 can be higher than the first insulating layer 2, equal to the first insulating layer 2 or lower than the first insulating layer 2 according to the requirement.

In one preferred embodiment of the present invention, the width “a” of the polysilicon melt 3 is smaller than the length “b” of the polysilicon melt 3. The width “a” of the polysilicon melt 3 (i.e., the critical dimension of the polysilicon melt) can be adjusted within the range of 55 nm-1 μm according to the actual requirement. Preferably, the width of the polysilicon melt 3 is within the range of 55 nm-300 nm.

Furthermore, a metal silicide layer 5 can be formed on the top of the polysilicon melt 3 to reduce the resistance of the polysilicon melt, thereby enabling a uniform current flow through the polysilicon melt and enhancing the blowing controllability. The metal silicide can be the reactant of metal and polysilicon, such as nickel silicide or tungsten silicide.

The fabrication method of the embedded polysilicon fuse of the present invention will be described in detail below by accompanying FIG. 5. Please refer to FIG. 5, FIG. 5 is a cross-section diagram showing the process steps for fabricating the fuse-link of the embedded polysilicon fuse of the present invention.

The fabrication method of the polysilicon fuse comprises the following steps:

Step S1: etching a substrate 1 to form a groove 4 in the substrate 1, and forming a first insulting layer 2 on a surface of the substrate 1 covering the groove 4;

Step S2: forming a polysilicon melt layer on the first insulting layer 2; the polysilicon melt layer is a polysilicon layer.

Step S3: forming a second insulting layer on the polysilicon melt layer;

Step S4: performing lithographic and etching processes to the second insulting layer and the polysilicon melt layer. The remaining polysilicon melt layer in the groove 4 with a certain height after etching forms a polysilicon melt 3.

In the present embodiment, step S1 includes: first performing a lithographic process to form a patterned photoresist layer on the substrate as a mask, and then performing a dry etching to the substrate to form the groove.

In step S1 and step S3, the formation of the insulating layer can be achieved by a furnace tube or other common measurements.

Preferably, step S2 includes: forming a polysilicon melt layer with a certain height on the first insulating layer by a chemical vapor deposition process.

Step S3 includes: firstly, forming a silicon nitride (SiN) layer 6 on the polysilicon melt layer, then forming a silicon dioxide layer 7 on the SiN layer 6. In other embodiments, the second insulating layer can be one layer of SiN, silicon dioxide or other insulating material, which functions as an etch stop layer. As shown in FIG. 5, since the polysilicon melt layer is deposited on the surface of the first insulating layer with a recessed shape, a recessed opening is formed on the upper surface of the polysilicon melt layer. Alternatively, the recessed opening can also be leveled up through process. For example, after the SiN layer 6 conformally forming on the upper surface of the polysilicon melt layer, the recessed opening is formed, then the silicon dioxide layer 7 covers on the SiN layer 6 to completely or incompletely fill up the recessed opening. The filling of the recessed opening has no substantial influence on the subsequent processes.

Step S4 includes: forming a patterned mask layer 8 on the second insulating layer, and performing a dry etching process to the second insulating layer and the polysilicon melt layer using the patterned mask layer 8 as the etching mask. In the embodiment, the dry etching process is an isotropic drying etching process. Alternatively, an anisotropic dry etching process can also be adopted to perform the dry etching in specific direction so as to form a vertical profile. It is noted that, in the anisotropic dry etching process, the etching width is determined according to the size of the photomask. Accordingly, in order to achieve a small etching width, a photomask of a corresponding small size is required, which is more expensive. By contrast, in the isotropic etching process, a photomask with larger size and relative low price can be used to achieve the small width etching, which is beneficial to cost saving.

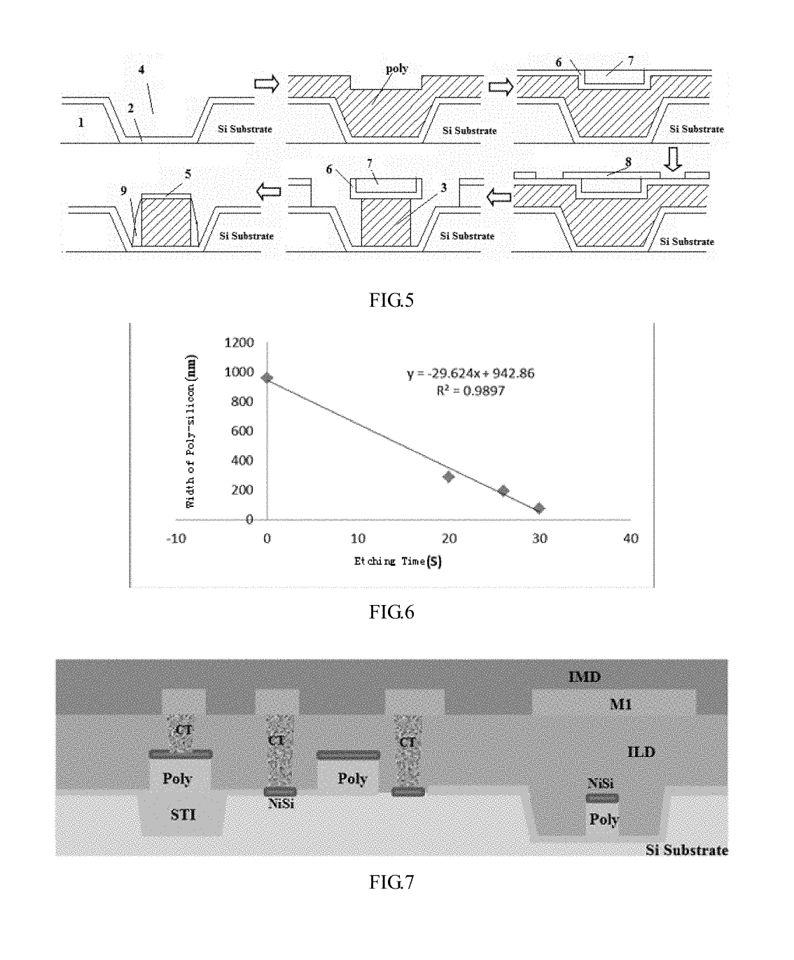

Please refer to FIG. 6, FIG. 6 is a diagram showing a relation between the width of the polysilicon melt and the dry etching time according to an embodiment of the present invention, which is obtained through experimental data collection and fitting. It can be found in the diagram that the width of the polysilicon melt is approximately linear to the etching time, that is, the critical dimension of the polysilicon melt decreases as the etching time increases. It will take about 30 seconds to etch a width of 60 nm.

Alternatively, the fabrication method further comprises step S5: removing the second insulating layer on the polysilicon melt by a wet etching process. The second insulating layer may not be removed. However, if step S6 is performed, the second insulating layer should be removed.

Alternatively, the fabrication method further comprises step S6: forming an insulating sidewall spacer 9 on two sides of the polysilicon melt 3. The insulating sidewall spacer can prevent short circuit of the metal silicide layer 5 which is formed in a subsequent step S7. The sidewall spacer 9 can be formed by chemical/physical vapor depositing silicon dioxide or silicon nitride.

Alternatively, the fabrication method further comprises step N7: performing a self-aligned silicidation process to form metal silicide on the top of the polysilicon melt, wherein the metal silicide is an alloy formed by the reaction between the metal such as nickel or tungsten and the polysilicon. The metal silicide reduces the resistance value of the polysilicon melt, enables a uniform current flow through the fuse-link, so as to enhance the blowing controllability.

The above processing steps have lower requirements for the photolithographic and dry etching apparatus. General etching apparatus can be applied to achieve an etching precision of 55 nm-300 nm, thereby efficiently saving the production cost. The etching process of the present invention can be performed by using the general lithographic apparatus and dry etching apparatus, and the width “a” can reach the precision of 55 nm-60 nm and 60 nm-300 nm.

Please refer to FIG. 7, FIG. 7 is schematic diagram showing the polysilicon fuse and the nearby devices. It can be seen that, since the polysilicon melt is embedded into the groove of the substrate rather than completely exposed on the substrate, the particles ejected when the melt is blown will be blocked by the sidewall of the groove and will not influence the operation of the nearby devices such as the MOSFETs.

The above is only the preferred embodiment of the present invention. Said embodiment is not intended to limit the patent protection scope of the present invention. Therefore, all of the equivalent structural changes made using the contents of the specification and drawings of the present invention, should be encompassed in the protection scope of the present invention in a similar way.

1. A fabrication method of the polysilicon fuse comprising the following steps:
step S1: etching a substrate to form a groove in the substrate, and forming a first insulting layer on a surface of the substrate covering the groove;
step S2: forming a polysilicon melt layer on the first insulting layer;
step S3: forming a second insulting layer on the polysilicon melt layer;
step S4: performing lithographic and etching processes to the second insulting layer and the polysilicon melt layer to form a polysilicon melt in the groove.

2. The fabrication method according to claim 7, further comprising:
step S5: removing the second insulting layer on the polysilicon melt by a wet etching process.

3. The fabrication method according to claim 8, further comprising:
step S6: forming an insulting sidewall spacer on two sides of the polysilicon melt.

4. The fabrication method according to claim 9, further comprising:
step S7: performing a self-aligned silicidation process to form a metal silicide layer on the top of the polysilicon melt.
